(19) United States
(12) Patent Application Publication
(10) Pub. No.: US 2026/0110731 A1
(43) Pub. Date: Apr. 23, 2026

(54) BURN-IN TESTING SYSTEM AND BURN-IN TESTING MODULE THEREOF

(71) Applicant: King Yuan Electronics Co., Ltd., Hsin-Chu (TW)

(72) Inventors: Chan-Yu WU, Hsin-Chu (TW); Yu-Chia CHANG, Hsin-Chu (TW); Hsung Liang CHANG, Hsin-Chu (TW)

(21) Appl. No.: 19/045,575

(22) Filed: Feb. 5, 2025

(30) Foreign Application Priority Data
Oct. 23, 2024 (TW) 113140373

(51) Int. Cl. G01R 31/28

(52) U.S. Cl. CPC G01R 31/2868; G01R 31/2863

(57) ABSTRACT

A burn-in test module includes a main frame, a connection card assembly, a driver board and a burn-in board. The connection card assembly is located on this main frame. The driver board is electrically connected to one side of the connector card assembly. The burn-in is electrically connected to the other side of the connection card assembly, wherein the main frame includes a first pair of parallel sliding rails that are slidingly connected with the burn-in board. The first pair of parallel sliding rails are perpendicular to a lengthwise direction of the connection card assembly.

### CROSS-REFERENCE TO RELATED APPLICATION

This application claims priority to Taiwan Application Serial Number 113140373, filed Oct. 23, 2024, which is herein incorporated by reference in its entirety.

### BACKGROUND

### Field of Disclosure

The present disclosure relates to a burn-in testing system and its burn-in testing module.

### Description of Related Art

In a conventional load-unload operation mode of a high-power burn-in board, the burn-in board must be replaced when the integrated circuit device under test is installed or uninstalled, which can easily cause the gold finger edge of the burn-in board to be worn out, and even improper manual handling can cause the burn-in board damaged.

As the size of the integrated circuit devices increases, the power of circuit chips also increases, the weight of high-power burn-in boards are increased to such degree that manual handling becomes difficult. In order to solve the above problems of high-power burn-in boards, the production line automation is needed.

### SUMMARY

The present disclosure provides a burn-in testing system and its burn-in testing module to deal with the needs of the prior art problems.

In one or more embodiments, a burn-in test system includes a furnace body, a multi-layer test rack and a burn-in test module. The furnace body includes a test chamber. The multi-layer test rack is located in the test chamber. The burn-in test module is slidably connected to each layer of the multi-layer test rack, wherein the burn-in test module includes a main frame and a burn-in board, wherein the main frame includes a first pair of parallel sliding rails that are slidably connected with the burn-in board.

In one or more embodiments, each layer of the multi-layer test rack includes a second pair of parallel sliding rails that are slidably connected with the main frame, and the second pair of parallel sliding rails are parallel to the first pair of parallel sliding rails.

In one or more embodiments, the burn-in test module further comprises a connection card assembly located on the main frame, the first pair of parallel sliding rails are perpendicular to a lengthwise direction of the connection card assembly.

In one or more embodiments, the main frame includes two parallel rods, the first pair of parallel sliding rails are located on the two parallel rods respectively, the burn-in board is assembled from an opening between the two parallel rods, and slidably connected with the first pair of parallel sliding rails.

In one or more embodiments, the burn-in test module further comprises a driver board electrically connected to one side of the connection card assembly, the driver board comprises a drag chain support plate and a movable drag chain, the movable drag chain is configured to be operable directly above the drag chain support plate.

In one or more embodiments, the burn-in test system further comprising a load-unload module, wherein the load-unload module comprises a plurality of upright rods, a platform slidably connected to the upright rods, a carrier tray located on the platform and configured to carry a plurality of integrated circuit devices to be tested, and a third pair of parallel sliding rails located on the platform and aligned with an opening of the test chamber.

In one or more embodiments, the load-unload module further comprises a movable assembly, wherein the movable assembly is located adjacent to the third pair of parallel sliding rails, and the movable assembly is configured to be movable between the load-unload module and the test chamber.

In one or more embodiments, the movable assembly is secured to the main frame of the burn-in test module, and the movable assembly is configured to move the burn-in test module from the test chamber to the load-unload module.

In one or more embodiments, an area of the burn-in test module containing at least the burn-in board is configured to be movable from the test chamber to the load-unload module.

In one or more embodiments, the load-unload module further comprises a disassembly-assembly mechanism disposed on the platform, and the disassembly-assembly mechanism is located between the burn-in test module and the platform, the burn-in test module further comprises a connection card assembly disposed on the main frame, the disassembly-assembly mechanism is connected to the main frame and the burn-in board respectively.

In one or more embodiments, the disassembly-assembly mechanism comprises a translation assembly and a stop assembly, the translation assembly is connected to the burn-in board, and the stop assembly is connected to the main frame adjacent to the connection card assembly, the translation assembly moves toward or away from the stop assembly to provide a driving force required for disassembly or assembly of the burn-in board and the connection card assembly.

In one or more embodiments, the platform is configured to slide on the upright rods in a first direction, and the third pair of parallel sliding rails extends in a second direction perpendicular to the first direction.

In one or more embodiments, the main frame of the burn-in test module is slidably connected with the second pair of parallel sliding rails and the third pair of parallel sliding rails when the third pair of parallel sliding rails are aligned and connected with the second pair of parallel sliding rails.

In one or more embodiments, a burn-in test module includes a main frame, a connection card assembly disposed on the main frame, a driver board electrically connected to one side of the connection card assembly, and a burn-in board is electrically connected to the other side of the connection card assembly, wherein the main frame comprises a first pair of parallel sliding rails slidably connected to the burn-in board, and the first pair of parallel sliding rails are perpendicular to a lengthwise direction of the connection card assembly.

In one or more embodiments, the driver board includes a storage device configured to store test software.

In one or more embodiments, the connection card assembly includes a power module.

In one or more embodiments, the main frame includes two parallel rods, and the first pair of parallel sliding rails are located on the two parallel rods respectively.

In one or more embodiments, the burn-in board is assembled from an opening of the two parallel rods and is slidably connected with the first pair of parallel sliding rails.

In one or more embodiments, the driver board and the burn-in board are electrically connected to two opposite sides of the connection card assembly.

In one or more embodiments, the main frame includes a second pair of parallel sliding rails slidably connected to the driver board, and the second pair of parallel sliding rails are perpendicular to the lengthwise direction of the connection card assembly.

In one or more embodiments, the main frame includes a second pair of parallel sliding rails slidably connected to the connection card assembly, and the second pair of parallel sliding rails are parallel to the lengthwise direction of the connection card assembly.

In one or more embodiments, the burn-in board includes a plurality of connection interfaces, a burn-in test is performed on a system board after the burn-in board is electrically connected to the system board via the connection interfaces.

In sum, the burn-in test system and module disclosed herein utilizes the main frame to carry the driver board, the connection card assembly and the burn-in board, and the main frame being moved in and out of the burn-in furnace body, which can reduce the time of taking and placing the integrated circuit device to be tested. The need to repeatedly plug and unplug the burn-in board will cause the risk of gold finger damaged and facilitate the replacement of driver boards and the connection card assembly, which will help increase maintenance efficiency and production line automation. The burn-in test module integrates the driver board, burn-in board and the connection card assembly into a unity by the main frame. The main frame includes sliding rails in two directions, which can be used for effective disassembly and assembly of the driver board, burn-in board and the connection card assembly to facilitate maintenance and module replacement. The burn-in test module can be installed from the main frame into the furnace body. The furnace body includes a multi-layer test rack to increase space utilization.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a perspective view of a burn-in test system according to an embodiment of the present disclosure;

FIG. 2 illustrates a perspective view of the burn-in test system in FIG. 1 with the load-unload module removed;

FIG. 3A illustrates a perspective view of the burn-in test system in FIG. 2 from another view point with a portion of the housing removed;

FIG. 3B illustrates a partially enlarged view of FIG. 3A;

FIG. 4 illustrates a partially enlarged view of the burn-in test system of FIG. 2;

FIG. 5 illustrates a partially enlarged perspective view of the burn-in test system of the present disclosure when the burn-in test module is unloaded;

FIG. 6 illustrates a perspective view of a burn-in test module according to the present disclosure;

FIG. 7 illustrates a partial exploded view of the burn-in test module in FIG. 6;

FIG. 8 illustrates a perspective view of the burn-in test module in FIG. 6 from another view point;

FIG. 9A illustrates a cross-sectional view of an engaging mechanism of a burn-in test module according to an embodiment of the present disclosure;

FIG. 9B illustrates a cross-sectional view of an engaging mechanism of a burn-in test module according to another embodiment of the present disclosure;

FIG. 10A is a schematic diagram showing a first state of the disassembly-assembly mechanism of the burn-in board according to the present disclosure;

FIG. 10B is a schematic diagram showing a second state of the disassembly-assembly mechanism of the burn-in board according to the present disclosure; and

FIG. 11 illustrates a cross-sectional view of testing a system board using a burn-in board according to the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

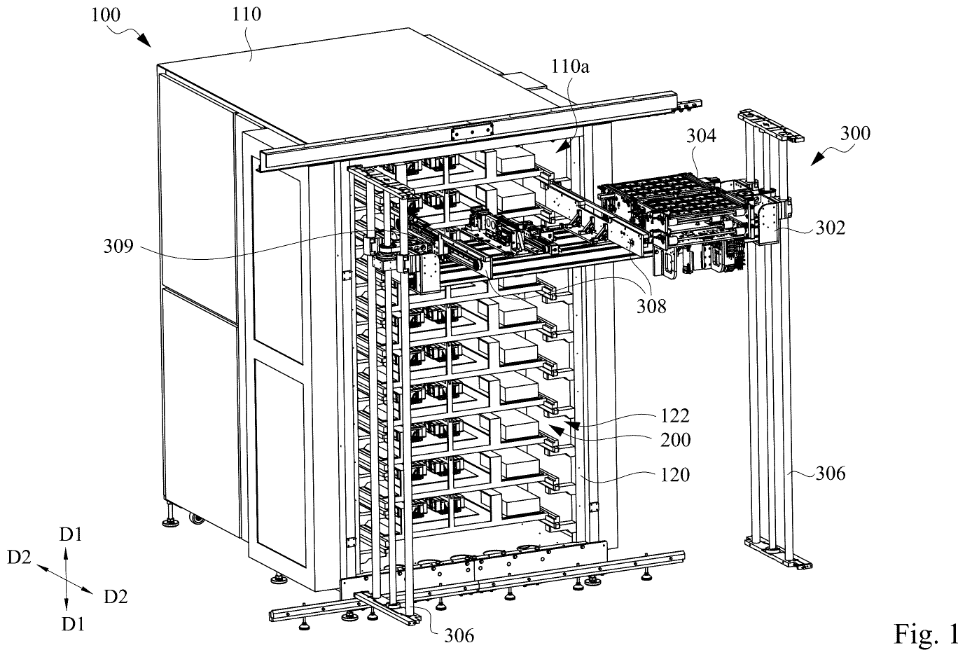

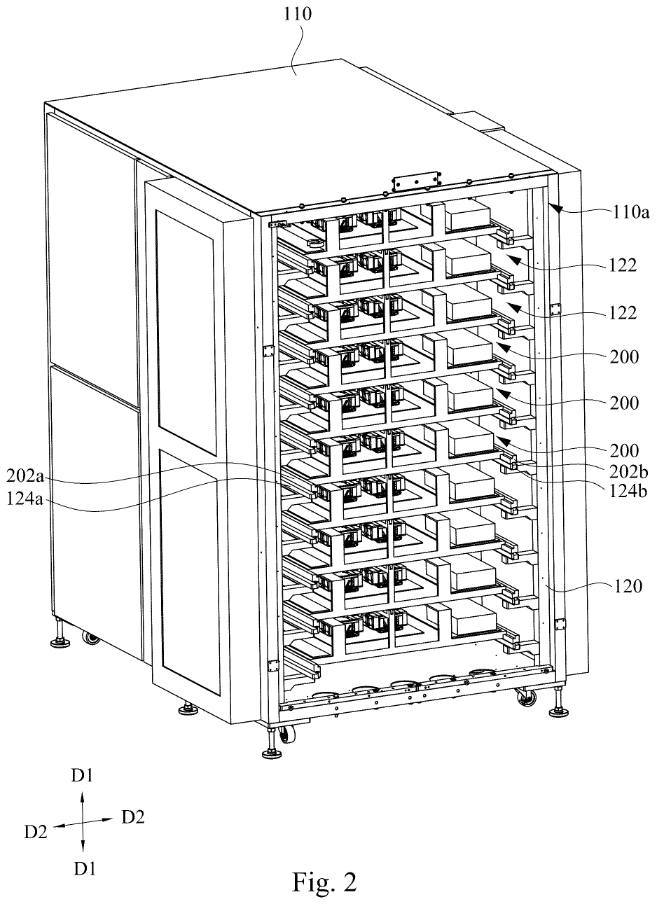

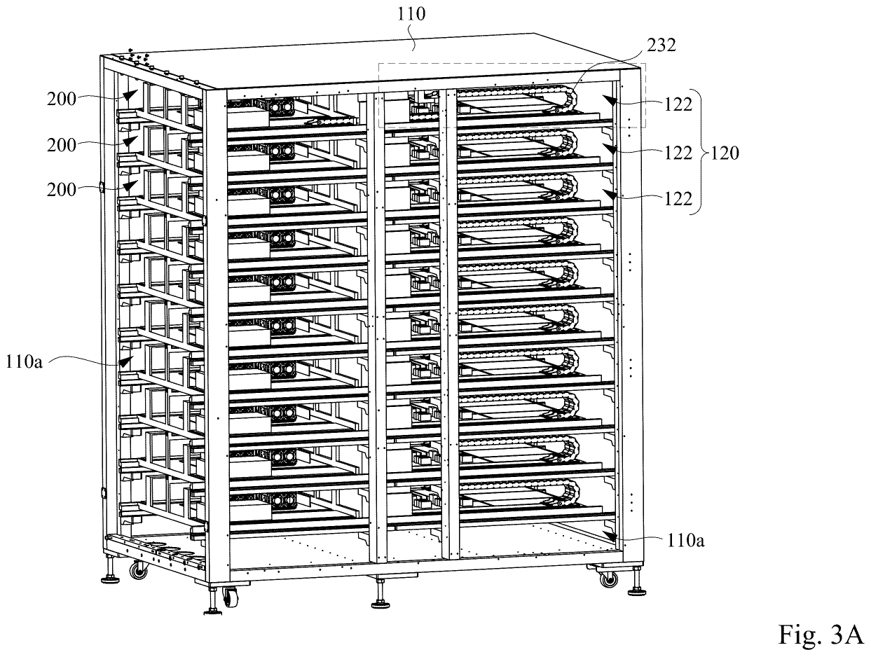

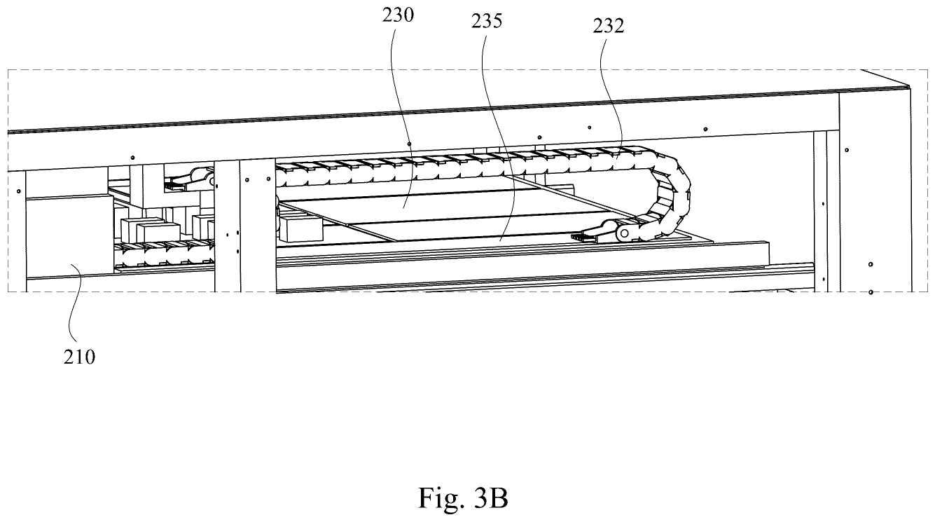

Reference is made to FIGS. 1 to 3A. FIG. 1 illustrates a perspective view of a burn-in test system according to an embodiment of the present disclosure, FIG. 2 illustrates a perspective view of the burn-in test system 100 in FIG. 1 with the load-unload module 300 removed, and FIG. 3A illustrates a perspective view of the burn-in test system in FIG. 2 from another view point with a portion of the housing removed. The burn-in test system 100 is a system for testing the reliability and stability of an integrated circuit (IC). The burn-in test system 100 utilizes the burn-in test to detect potential defects and failures early by running the device under high temperature conditions for a period of time, thereby improving product quality and reliability. The burn-in test system 100 includes a furnace body 110 and a load-unload module 300. The furnace body 110 includes a test chamber 110a. A multi-layer test rack 120 is located in the test chamber 110a. Each layer 122 of the multi-layer test rack 120 can accommodate a burn-in test module 200 for performing a burn-in test. In some embodiments of the present invention, each layer 122 of the multi-layer test rack 120 includes a pair of parallel sliding rails (124a, 124b) that are slidably connected to the main frame of the burn-in test module 200.

In some embodiments of the present disclosure, the load-unload module 300 includes a plurality of upright rods 306, a platform 302, a carrier tray 304, and a pair of parallel sliding rails 308. The two sides of the platform 302 are slidably connected to the upright rods 306 so that the platform 302 can move up and down along the direction D1 (vertical direction). The carrier tray 304 is located on the platform 302 and is used to carry a plurality of integrated circuit devices to be tested. The pair of parallel sliding rails 308 are located on the platform 302 and aligned with the opening of the test chamber 110a. The pair of parallel sliding rails 308 extend in a direction D2, which is perpendicular to the direction D1. The pair of parallel sliding rails 308 is used to load the burn-in test module 200 into or out of the test chamber 110a in a direction D2 (horizontal direction).

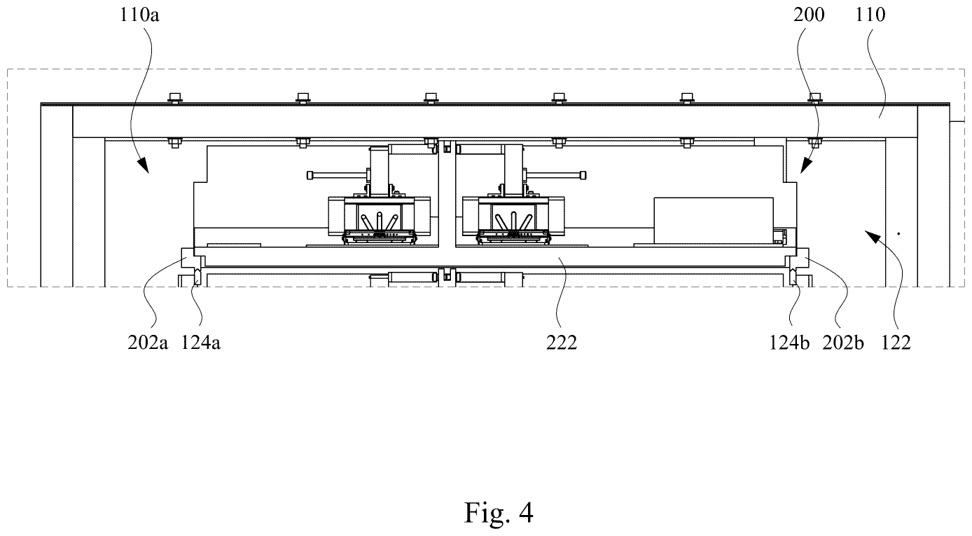

Reference is made to FIG. 4 illustrating a partially enlarged view of the burn-in test system 100 of FIG. 2. This view is an enlarged view of an open side of the test chamber 110a, which shows a single layer 122 of the multi-layer test rack and a single burn-in test module 200 accommodated therein. The two parallel rods (202a, 202b) of the burn-in test module 200 are slidably connected to a pair of parallel sliding rails (124a, 124b) of the multi-layer test rack.

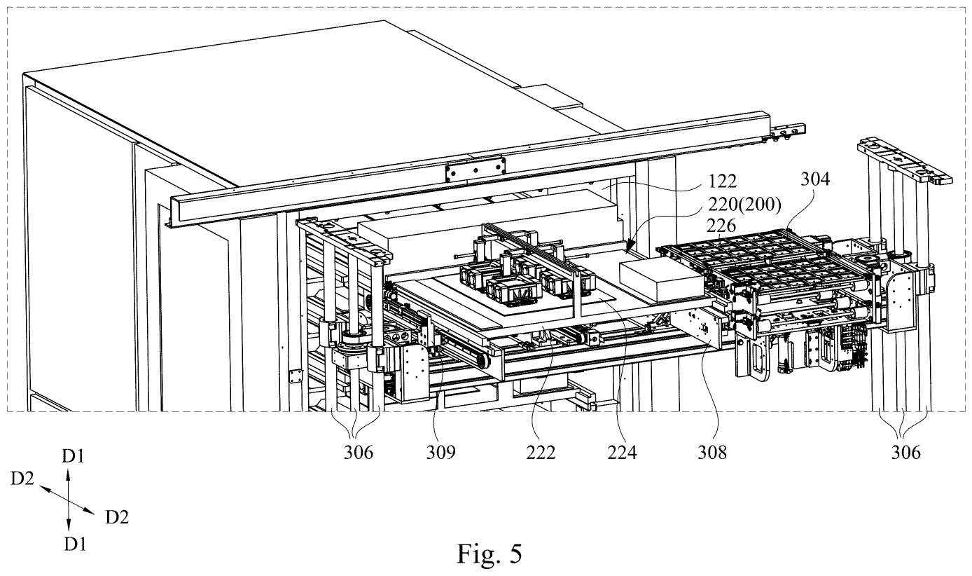

Reference is made to FIGS. 4 and 5. FIG. 5 illustrates a partially enlarged perspective view of the burn-in test system 100 of the present disclosure when the burn-in test module 200 is unloaded. The load-unload module 300 further includes a movable assembly 309 (see FIG. 1). The movable assembly 309 is located adjacent to the parallel sliding rail 308. The movable assembly 309 can be driven by any of a cylinder, a screw, a motor, or a belt into the test chamber 110a, and the movable assembly 309 is moved close to the main frame 201, in contact with the main frame 201, and fixed to the main frame 201. Then, the movable assembly 309 is driven by any moving method such as a cylinder, a screw, a motor, or a belt to move the burn-in test module 200, and move at least a portion of the burn-in test module 200 out of the test chamber 110a. When a pair of parallel sliding rails 308 of the load-unload module 300 is aligned with a corresponding pair of parallel sliding rails (124a, 124b) of the multi-layer test rack 120, the movable assembly 309 can be moved between the load-unload module 300 and the test chamber 110a by a method according to the above description, and at least a portion of the burn-in test module 200 is driven by the movable assembly 309 to be out of the test chamber 110a, and an area of the burn-in test module 200 containing at least the burn-in board 220 is moved to the load-unload module 300. The main frame 201 (e.g., 202a/202b in the figure) of the single burn-in test module 200 can be driven by the movable assembly 309 and slide on the parallel sliding rails 308 and the parallel sliding rails (124a, 124b), a single burn-in test module 200 can be loaded into or unloaded from the test chamber 110a in the direction D2, wherein the design of the movable assembly 309 located in the load-unload module 300 can enable a single movable assembly 309 to correspond to column groups of burn-in test modules 200 and the load-unload modules 300 can be moved between the layers 122 of the multi-layer test rack 120, and the movable assembly 309 can move each burn-in test module 200 to the load-unload module 300 to enable the burn-in test module 200 to be moved to the load-unload module 300. The movable assembly 309 moves an area of the burn-in test module 200 including at least the burn-in board 220 out of the test chamber 110a for replacing the burn-in board 220 or loading/unloading devices to be tested, and then other modules are used to replace the burn-in board 220 of the burn-in test module 200 or load/unload devices to be tested. After replacing the burn-in board 220 or loading/unloading devices to be tested, the movable assembly 309 moves the area of the burn-in test module 200 including at least the burn-in board 220 from a position of the load-unload module 300 back to the test chamber 110a. Finally, the movable assembly 309 moves the burn-in test module 200 back to the test chamber 110a. After the movable assembly 309 is separated from the main frame 201 and moved out of the multi-layer test rack 120, and the moving operation between the test chamber 110a and the load-unload module 300 is completed. The load-unload module 300 is configured with a single movable assembly 309. The design can not only effectively save the cost of equipment construction, but also can flexibly move multiple groups of burn-in test modules 200 in coordination with the movement of the load-unload module 300. In another embodiment, the movable assembly 309 may be located on the multi-layer test rack 120 or the sliding rails (124a, 124b). In this embodiment, the movable assembly 309 and the burn-in test module 200 are designed one-to-one. When the parallel sliding rails 308 of the load-unload module 300 are docked with the parallel sliding rails (124a, 124b) corresponding to the burn-in test module 200 to be moved in the multi-layer test rack 120, the movable assembly 309 moves closer to the main frame 201, contact and fix to the main frame 201, the movable assembly 309 can drive the burn-in test module 200 in and out of the test chamber 110a by any driving method such as cylinder, screw, motor and belt. This design can be quickly operated by the burn-in test module 200 being movable onto the load-unload module 300 by means of the multi-layer test rack 120, thereby effectively shortening the moving time of the burn-in test module 200. When a portion of the single burn-in test module 200 (such as the burn-in board 220) extends out of the test chamber 110a, integrated circuit (IC) devices 226 to be tested can be moved from the burn-in board 220 to the carrier tray 304 or from the carrier tray 304 to the burn-in board 220. When one layer 122 of the multi-layer test rack 120 has completed loading or unloading the IC devices 226 to be tested, the movable assembly 309 is separated from the main frame 201, and the platform 302 can move to a next layer 122 in the direction D1, the burn-in board 220 of the single burn-in test module 200 is extended out of the test chamber 110a and moved to an area of the load-unload module 300 to perform loading or unloading of the integrated circuit device 226 to be tested. The burn-in test module 200 in all layers 122 of the multi-layer test rack 120 will continue load or unload all the IC devices 226 to be tested.

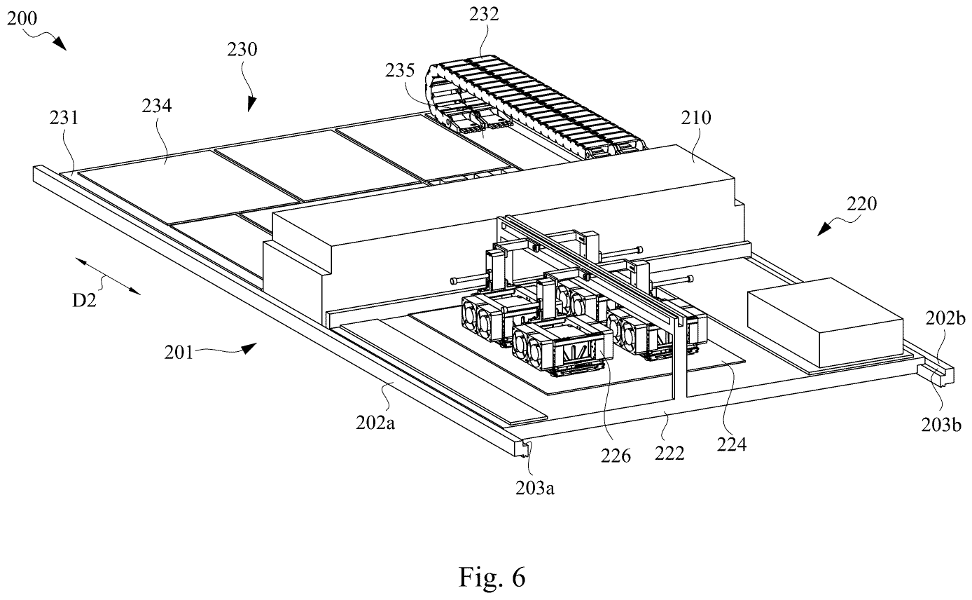

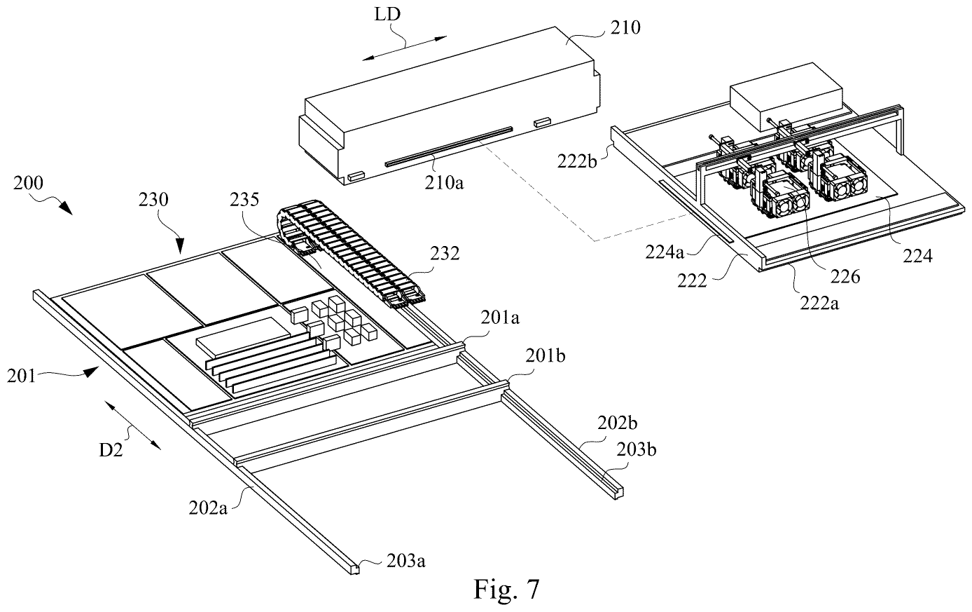

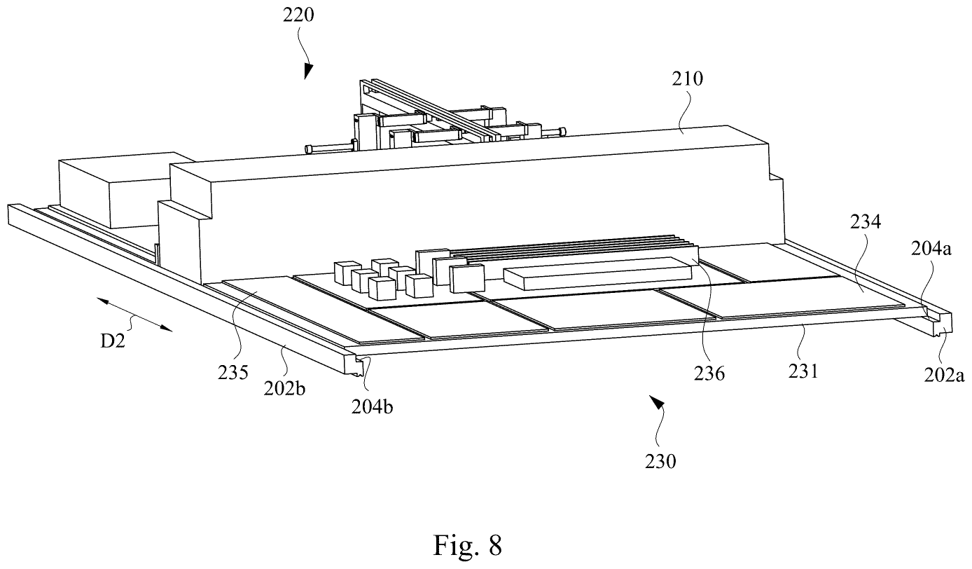

Reference is made to FIGS. 6 to 8. FIG. 6 illustrates a perspective view of a burn-in test module 200 according to the present disclosure. FIG. 7 illustrates a partial exploded view of the burn-in test module 200 in FIG. 6. FIG. 8 illustrates a perspective view of the burn-in test module 200 in FIG. 6 from another view point (with the movable drag chain 232 removed) from another perspective. The burn-in test module 200 includes a main frame 201, a connection card assembly 210, a driver board 230 and a burn-in board 220. The connection card assembly 210 is located on the main frame 201. The driver board 230 is electrically connected to one side of the connection card assembly 210, and the burn-in board 220 is electrically connected to the other side of the connection card assembly 210. The driver board 230 and the burn-in board 220 are electrically connected to two opposite sides of the connection card assembly 210. The main frame 201 includes a pair of parallel sliding rails (203a, 203b) slidably connected to the burn-in board 220, and the pair of parallel sliding rails (203a, 203b) and another pair of parallel sliding rails (201a, 201b) are perpendicular to each other. The connection card assembly 210 can be assembled on the main frame 201 by means of the sliding rails (201a, 201b), and a lengthwise direction LD of the connection card assembly 210 is parallel to a lengthwise direction LD of the sliding rails (201a, 201b) in the connection card assembly 210.

In some embodiments of the present invention, the driver board 230 includes a storage device 236 (e.g., a read-only memory) for storing software required for burn-in tests. In some embodiments of the present invention, the connection card assembly 210 includes a power module required for burn-in tests.

In some embodiments of the present invention, the burn-in board 220 includes a frame 222, a circuit board 224, and a gold finger connecting board edge 224a. The circuit board 224 includes a plurality of sockets for plugging the IC devices 226 to be tested. The frame 222 is located around a periphery of the circuit board 224.

In some embodiments of the present invention, the main frame 201 includes two parallel rods (202a, 202b), and the two parallel rods (202a, 202b) are provided with a pair of parallel sliding rails (203a, 203b). The burn-in board 220 can be assembled from an opening between the parallel sliding rails (203a, 203b), so that the two frame edges (222a, 222b) of the frame 222 are slidably connected to the two parallel sliding rails (203a, 203b) respectively. When the burn-in board 220 moves toward the connection card assembly 210 along the two parallel sliding rails (203a, 203b) , the gold finger connection board edge 224a of the burn-in board 220 will be inserted into a slot 210a of the connection card assembly 210 to achieve electrical connection. Another pair of parallel sliding rails (204a, 204b) are provided on the two parallel rods (202a, 202b). The parallel sliding rails (204a, 204b) enable the driver board 230 to be connected to the connection card assembly 210 in a manner similar to the parallel sliding rails (203a, 203b). The direction of the sliding rails (201a, 201b) is different from the direction of the sliding rails (203a, 203b) and the sliding rails (204a, 204b), so that the disassembly and assembly sliding direction of the connection card assembly 210 is different from that of the driver board 230 or the burn-in board 220, which can effectively avoid interference during installation or removal.

Reference is made to FIGS. 3A, 3B, and 6. In some embodiments of the present invention, the driver board 230 includes a frame 231, a circuit board 234, a drag chain support plate 235, and a movable drag chain 232 and a storage device 236. The drag chain support plate 235 is arranged side by side with the circuit board 234 and is surrounded by the frame 231 at its periphery. The movable drag chain 232 is used to accommodate the wire/signal wire (not shown in the figure) associated with the connection card assembly 210 and the driver board 230 therein, one end of the wire is fixed to the furnace body 110 for connecting to an external power source and signal transmission, and the other end of the wire is fixed to the drag chain support plate 235, and is electrically connected to the connection card assembly 210 and the driver board 230 respectively. The wire/signal wire, the connection card assembly 210 and the driver board 230 can be plugged in and installed by an electrical connection interface, so that each module in the burn-in test module 200 can be flexibly replaced according to demand. The burn-in test module 200 adopts the design of the movable loading and unloading test chamber 110a. The design of the movable drag chain 232 effectively avoids the pulling and interference of the wires, and can stably provide the signal and power supply of the burn-in test module 200, and can meet the power supply and test signal stable supply after the flexible replacement of each module.

When the driver board 230 slides in the direction D2, the wire/signal wire should be prevented from interfering with components on the circuit board 234. When the movable drag chain 232 slides on the driver board 230 along the direction D2, the movable drag chain 232 is only operable directly above the drag chain support plate 235, thereby reducing the interference between the movable drag chain 232 and components on the circuit board 234.

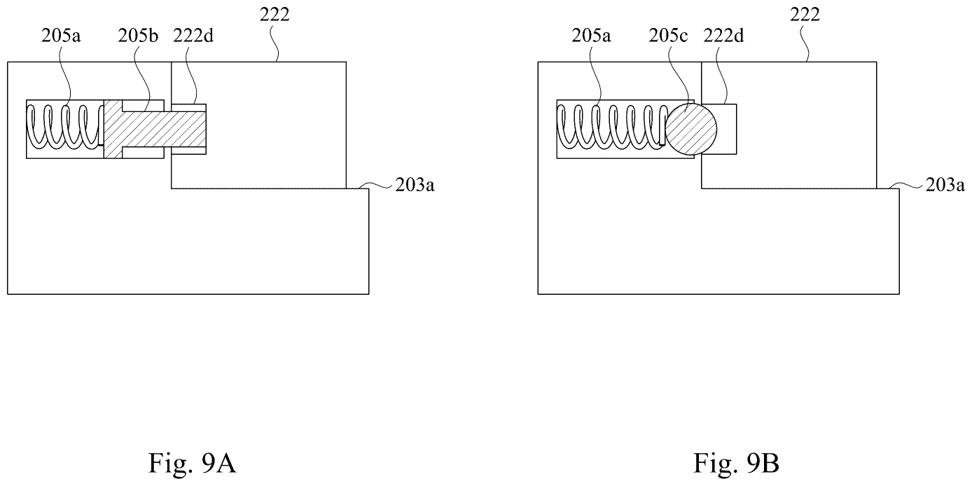

Reference is made to FIGS. 9A and 9B, which are cross-sectional views of engaging mechanisms of a burn-in test module according to embodiments of the present disclosure. The engaging mechanism is used to position the burn-in board 220 and the driver board 230 on the sliding rail of the main frame 201. FIGS. 9A and 9B only illustrate the engaging mechanism related to the burn-in board 220. The sidewall of the frame 222 of the burn-in board 220 has a positioning groove 222d. The sidewall of the sliding rail 203a has an elastic member 205a and a positioning column 205b. The elastic force of the elastic member 205a is used to provide a thrust to the positioning column 205b so that the positioning column 205b protrudes out of an opening of the sidewall of the sliding rail 203a. When the positioning groove 222d is aligned with the positioning column 205b, the positioning post 205b is inserted into the positioning groove 222d to position the burn-in board 220 on the sliding rail 203a. When the positioning column 205b is withdrawn from the positioning groove 222d, the burn-in board 220 can slide along the sliding rail 203a. The embodiment of FIG. 9B is different from the embodiment of FIG. 9A in that positioning beads 205c are used to replace positioning columns 205b. In another embodiment, the positioning groove can be located on the sidewall of the sliding rail 203a, and the elastic member 205a and the positioning column 205b or the positioning bead 205c can be located on the sidewall of the frame 222 of the burn-in board 220. The design of the positioning groove 222d, the elastic member 205a and the positioning column 205b or the positioning bead 205c can stably fix the burn-in board 220 on the sliding rail 203a.

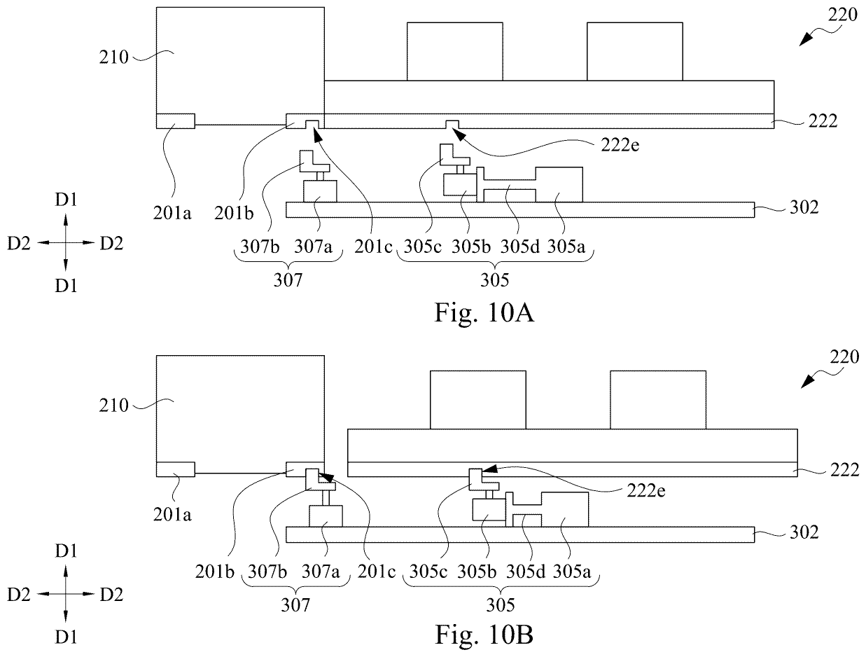

Reference is made to FIGS. 10A and 10B, which illustrate schematic diagrams showing two states of the disassembly-assembly mechanism of the burn-in board according to the present invention. The load-unload module further includes a disassembly-assembly mechanism, which is installed on the platform 302, and when the burn-in test module 200 is moved out of the test chamber 110a, the disassembly-assembly mechanism is sandwiched between the burn-in test module 200 and the platform 302, and the disassembly-assembly mechanism is used to disassemble (FIG. 10B) or assemble (FIG. 10A) the burn-in board 220 from the connection card assembly 210, thereby completing the function of automatically installing the burn-in board. The disassembly-assembly mechanism includes a translation assembly 305 and a stop assembly 307, wherein the translation assembly 305 can be connected to the frame 222 of the burn-in board 220, and the stop assembly 307 can be connected to the main frame 201 adjacent to the connection card assembly 210. The connection and separation between the burn-in board 220 and the connection card assembly 210 are achieved by moving the translation assembly 305 and the stop assembly 307 closer and farther away. The stop assembly 307 includes a driving member 307a and a stopping fastener 307b fixed on the platform 302. The driving member 307a is used to drive the stopping fastener 307b to move up and down in a direction D1 (e.g., a vertical direction). The stop fastener 307b is used to be inserted into a stop groove 201c of the main frame 201 adjacent to the connection card assembly 210 to fix the connection card assembly 210 to the main frame 201. The translation assembly 305 includes a horizontal driving member 305a, a vertical driving member 305b, a translation fastener 305c and a horizontal rod 305d. The horizontal driving member 305a drives the horizontal rod 305d to move in the direction D2 (e.g., a horizontal direction). The vertical driving member 305b is located at an end of the horizontal rod 305d and is used to drive the translation fastener 305c to move up and down in the direction D1. The translation fastener 305c is used to be inserted into the fastening groove 222e of the frame 222 of the burn-in board 220. When the horizontal driving member 305a moves toward or away from the stop assembly 307 in the direction D2, the horizontal driving member 305a provides the burn-in board 220 a driving force required to disassemble or assemble with the connection card assembly 210.

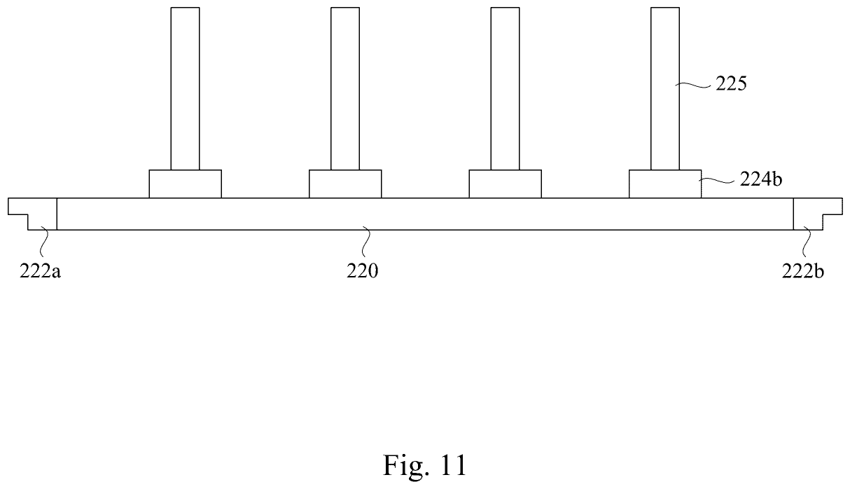

Reference is made to FIG. 11, which illustrates a cross-sectional view of testing a system board using a burn-in board according to the present disclosure. In other embodiments of the present invention, the burn-in board 220 can also perform a burn-in test on a system board 225. The system board 225 is a circuit board used in actual applications, which carries and connects all the IC devices to be tested and provides power supply and signal transmission. The system board 225 is also a part of the final product and is directly used for the actual operation of the device. When the device to be tested is a system board 225 for burn-in test, the system board 225 is also placed on the carrier tray 304 for transportation. After being transported to the load-unload module 300, the system board 225 is replaced between the carrier tray 304 and the burn-in board. 220, the burn-in board 220 and the system board 225 can be electrically connected via a connection interface 224b and then a burn-in test can be performed.

In sum, the burn-in test system and module disclosed herein utilizes the main frame to carry the driver board, the connection card assembly and the burn-in board, and the main frame being moved in and out of the burn-in furnace body, which can reduce the time of taking and placing the integrated circuit device to be tested. The need to repeatedly plug and unplug the burn-in board will cause the risk of gold finger damaged and facilitate the replacement of driver boards and the connection card assembly, which will help increase maintenance efficiency and production line automation. The burn-in test module integrates the driver board, burn-in board and the connection card assembly into a unity by the main frame. The main frame includes sliding rails in two directions, which can be used for effective disassembly and assembly of the driver board, burn-in board and the connection card assembly to facilitate maintenance and module replacement. The burn-in test module can be installed from the main frame into the furnace body. The furnace body includes a multi-layer test rack to increase space utilization.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A burn-in test system comprising:
a furnace body including a test chamber;
a multi-layer test rack disposed in the test chamber; and
a burn-in test module slidably connected to each layer of the multi-layer test rack, wherein the burn-in test module includes a main frame and a burn-in board, wherein the main frame includes a first pair of parallel sliding rails that are slidably connected with the burn-in board.

2. The burn-in test system of claim 1, wherein each layer of the multi-layer test rack includes a second pair of parallel sliding rails that are slidably connected with the main frame, and the second pair of parallel sliding rails are parallel to the first pair of parallel sliding rails.

3. The burn-in test system of claim 1, wherein the burn-in test module further comprises a connection card assembly located on the main frame, the first pair of parallel sliding rails are perpendicular to a lengthwise direction of the connection card assembly.

4. The burn-in test system of claim 1, wherein the main frame includes two parallel rods, the first pair of parallel sliding rails are located on the two parallel rods respectively, the burn-in board is assembled from an opening between the two parallel rods, and slidably connected with the first pair of parallel sliding rails.

5. The burn-in test system of claim 3, wherein the burn-in test module further comprises a driver board electrically connected to one side of the connection card assembly, the driver board comprises a drag chain support plate and a movable drag chain, the movable drag chain is configured to be operable directly above the drag chain support plate.

6. The burn-in test system of claim 2, further comprising a load-unload module, wherein the load-unload module comprises:
a plurality of upright rods;
a platform slidably connected to the upright rods;
a carrier tray located on the platform and configured to carry a plurality of integrated circuit devices to be tested; and
a third pair of parallel sliding rails located on the platform and aligned with an opening of the test chamber.

7. The burn-in test system of claim 6, wherein the load-unload module further comprises a movable assembly, wherein the movable assembly is disposed adjacent to the third pair of parallel sliding rails, and the movable assembly is configured to be movable between the load-unload module and the test chamber.

8. The burn-in test system of claim 7, wherein the movable assembly is secured to the main frame of the burn-in test module, and the movable assembly is configured to move the burn-in test module from the test chamber to the load-unload module.

9. The burn-in test system of claim 8, wherein an area of the burn-in test module containing at least the burn-in board is configured to be movable from the test chamber to the load-unload module.

10. The burn-in test system of claim 9, wherein the load-unload module further comprises a disassembly-assembly mechanism disposed on the platform, and the disassembly-assembly mechanism is located between the burn-in test module and the platform, the burn-in test module further comprises a connection card assembly disposed on the main frame, the disassembly-assembly mechanism is connected to the main frame and the burn-in board respectively.

11. The burn-in test system of claim 10, wherein the disassembly-assembly mechanism comprises a translation assembly and a stop assembly, the translation assembly is connected to the burn-in board, and the stop assembly is connected to the main frame adjacent to the connection card assembly, the translation assembly moves toward or away from the stop assembly to provide a driving force required for disassembly or assembly of the burn-in board and the connection card assembly.

12. The burn-in test system of claim 6, wherein the platform is configured to slide on the upright rods in a first direction, and the third pair of parallel sliding rails extends in a second direction perpendicular to the first direction.

13. The burn-in test system of claim 12, wherein the main frame of the burn-in test module is slidably connected with the second pair of parallel sliding rails and the third pair of parallel sliding rails when the third pair of parallel sliding rails are aligned and connected with the second pair of parallel sliding rails.

14. A burn-in test module comprising:
a main frame;
a connection card assembly disposed on the main frame;
a driver board electrically connected to one side of the connection card assembly; and
a burn-in board is electrically connected to the other side of the connection card assembly, wherein the main frame comprises a first pair of parallel sliding rails slidably connected to the burn-in board, and the first pair of parallel sliding rails are perpendicular to a lengthwise direction of the connection card assembly.

15. The burn-in test module of claim 14, wherein the driver board comprises a storage device configured to store test software.

16. The burn-in test module of claim 14, wherein the connection card assembly comprises a power module.

17. The burn-in test module of claim 14, wherein the main frame comprises two parallel rods, and the first pair of parallel sliding rails are located on the two parallel rods respectively.

18. The burn-in test module of claim 17, wherein the burn-in board is assembled from an opening of the two parallel rods and is slidably connected with the first pair of parallel sliding rails.

19. The burn-in test module of claim 14, wherein the driver board and the burn-in board are electrically connected to two opposite sides of the connection card assembly.

20. The burn-in test module of claim 14, wherein the main frame comprises a second pair of parallel sliding rails slidably connected to the driver board, and the second pair of parallel sliding rails are perpendicular to the lengthwise direction of the connection card assembly.

21. The burn-in test module of claim 14, wherein the main frame comprises a second pair of parallel sliding rails slidably connected to the connection card assembly, and the second pair of parallel sliding rails are parallel to the lengthwise direction of the connection card assembly.

22. The burn-in test module of claim 14, wherein the burn-in board comprises a plurality of connection interfaces, a burn-in test is performed on a system board after the burn-in board is electrically connected to the system board via the connection interfaces.
